(19) United States
(12) Patent Application Publication
(10) Pub. No.: US 2018/0010240 A1
(43) Pub. Date: Jan. 11, 2018

(54) ARC DISCHARGE GENERATION DEVICE AND FILM FORMATION METHOD

(71) Applicant: TOYOTA JIDOSHA KABUSHIKI KAISHA, Toyota-shi (JP)

(72) Inventors: Takayasu SATO, Takahama-shi (JP); Yoji SATO, Kasugai-shi (JP); Kazutaka TACHIBANA, Nagoya-shi (JP)

(73) Assignee: TOYOTA JIDOSHA KABUSHIKI KAISHA, Toyota-shi (JP)

(21) Appl. No.: 15/636,036

(22) Filed: Jun. 28, 2017

(30) Foreign Application Priority Data
Jul. 7, 2016 (JP) 2016-135077

(51) Int. Cl. C23C 14/32; C23C 14/54

(52) U.S. Cl. CPC C23C 14/325; C23C 14/54

(57) ABSTRACT

An arc discharge generation device energizes an evaporation source with the power supply device so that the evaporation source functions as a negative electrode to have a striker chip contact the evaporation source and then separate the striker chip from the evaporation source to generate an arc discharge in the chamber. When extinguishing the arc discharge generated in the chamber, the arc discharge generation device has the striker chip contact the evaporation source and de-energizes the evaporation source with the power supply device in a situation in which the striker chip is in contact with the evaporation source.

### BACKGROUND OF THE INVENTION

The present invention relates to an arc discharge generation device that generates an arc discharge in a chamber and a method for forming a film on a work with an arc ion plating method.

Japanese Laid-Open Patent Publication No. 2011-138671 discloses an example of a film formation device that forms a film on a work with an arc ion plating method. In the film formation device, a power supply device energizes an evaporation source so that the evaporation source functions as a negative electrode. Further, a striker is brought into contact with the evaporation source and then immediately separated from the evaporation source to generate electric sparks. In a chamber, an arc discharge is generated between the evaporation source, which functions as the negative electrode, and a positive electrode. Ions are emitted from the evaporation source by the arc discharge. In this manner, when the ions emitted from the evaporation source are deposited on the work, a film is formed on the work. When the striker is not generating electric sparks, the striker waits at a retraction position that is separated from the evaporation source.

In general, a power supply device that energizes an evaporation source includes multiple types of circuit elements such as a resistor and a coil. In this configuration, when the power supply device de-energizes the evaporation source to extinguish an arc discharge generated in a chamber, a high voltage is generated at the coil and applied to the evaporation source. If a portion of a wall surface of the chamber that is insufficiently insulated is located proximate to the evaporation source, an arc discharge may be generated between that portion and the evaporation source.

### SUMMARY OF THE INVENTION

It is an object of the present invention to provide an arc discharge generation device and a film formation method that limit the generation of an arc discharge between an evaporation source and a portion of a wall surface of a chamber when a power supply device de-energizes the evaporation source to extinguish an arc discharge generated in the chamber.

To solve the above problem, an arc discharge generation device according to a first aspect of the present invention includes an evaporation source located in a chamber, a striker configured to be movable in the chamber, an actuator that drives and moves the striker, a power supply device that energizes the evaporation source, and a controller that controls the actuator and the power supply device. The controller energizes the evaporation source with the power supply device so that the evaporation source functions as a negative electrode and controls the actuator to have the striker contact the evaporation source and then separate the striker from the evaporation source to generate an arc discharge in the chamber and emit ions from the evaporation source through the arc discharge. When extinguishing the arc discharge generated in the chamber, the controller controls the actuator to have the striker contact the evaporation source and de-energize the evaporation source with the power supply device in a situation in which the striker is in contact with the evaporation source.

In this structure, when the striker contacts the evaporation source, an electric circuit including the evaporation source is formed. When the power supply device de-energizes the evaporation source, a high voltage is generated at a coil of the power supply device and applied to the evaporation source. Since current flows through the electric circuit, the potential difference between the evaporation source and a wall surface of the chamber does not become large. This limits the generation of an arc discharge between a portion of the wall surface of the chamber and the evaporation source.

When an arc discharge is generated in the chamber, the temperature of the evaporation source becomes high. Thus, when the striker contacts the high-temperature evaporation source to extinguish the arc discharge, the temperature of a contact portion of the striker that contacts the evaporation source rises. In this case, transmission of heat from the evaporation source increases the temperature of the contact portion. Thus, the contact portion may melt so that the striker is welded to the evaporation source.

Thus, it is preferred that the striker include a contact portion that contacts the evaporation source and that the contact portion be formed from a sublimable material. In this structure, when the striker contacts the evaporation source that has a high temperature, the temperature of the contact portion may rise. In this case, the material of the contact portion may undergo a phase transition from a solid to a gas through sublimation but will seldom undergo a phase transition from a solid to a liquid. This limits welding of the striker to the evaporation source.

It is preferred that a sublimation point of a material that forms the contact portion of the striker be higher than a boiling point of a material that forms the evaporation source. In this structure, when the contact portion of the striker contacts the evaporation source that has a high temperature, the material of the contact portion will seldom sublime.

Further, the striker may include a contact portion that contacts the evaporation source, and a melting point of a material that forms the contact portion may be higher than a boiling point of a material that forms the evaporation source. In this structure, when the contact portion of the striker contacts the evaporation source that has a high temperature, the material of the contact portion will seldom melt. That is, welding of the striker to the evaporation source is limited.

To solve the above problem, a method for forming a film according to a second aspect of the present invention includes energizing an evaporation source arranged in a chamber with a power supply device so that the evaporation source functions as a negative electrode, generating an arc discharge in the chamber by having a striker contact the evaporation source and then separating the striker from the evaporation source, and forming a film on a work with ions emitted from the evaporation source by the arc discharge. When extinguishing the arc discharge generated in the chamber, the method has the striker contact the evaporation source and de-energizes the evaporation source with the power supply device under a situation in which the striker is in contact with the evaporation source. In this method, the same advantage as the arc discharge generation device is obtained.

Other aspects and advantages of the present invention will become apparent from the following description, taken in conjunction with the accompanying drawings, illustrating by way of example the principles of the invention.

### BRIEF DESCRIPTION OF THE DRAWINGS

The invention, together with objects and advantages thereof, may best be understood by reference to the following description of the presently preferred embodiments together with the accompanying drawings in which:

FIG. 1 is a schematic diagram showing a film formation device that includes an arc discharge generation device according to one embodiment of the present invention;

FIG. 2 is a flowchart showing a processing routine executed by the arc discharge generation device when extinguishing an arc discharge generated in a chamber; and

FIG. 3 is a diagram showing the operation of the arc discharge generation device when extinguishing an arc discharge generated in the chamber.

### DETAILED DESCRIPTION OF THE PREFERRED EMBODIMENTS

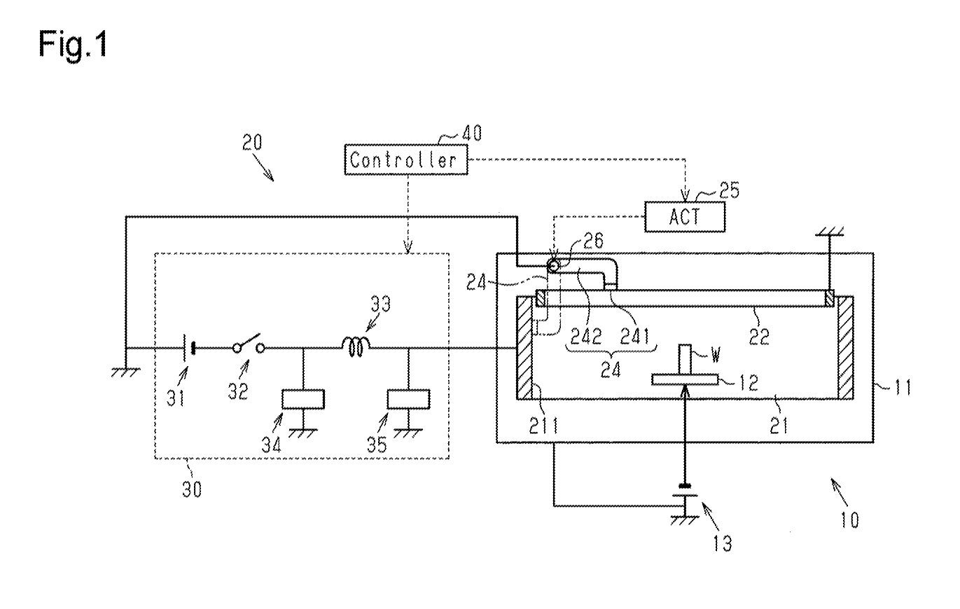

One embodiment of an arc discharge generation device and a film formation method according to the present invention will now be described with reference to FIGS. 1 to 3.

FIG. 1 shows a film formation device 10 that forms a film on a work W with an arc ion plating method. As shown in FIG. 1, the film formation device 10 includes an arc discharge generation device 20, a chamber 11, a support 12, and a bias power supply 13. The interior of the chamber 11 is a vacuum atmosphere. The support 12 supports the work W in the chamber 11. The bias power supply 13 applies a negative bias voltage to the work W, which is supported by the support 12.

The arc discharge generation device 20 includes an evaporation source 21 and a positive electrode member 22. The evaporation source 21 is located in the chamber 11. The positive electrode member 22 is located above the support 12 in the chamber 11. The positive electrode member 22 is connected to ground.

The evaporation source 21 is formed from a metal (for example, titanium) and is generally tubular. In the same manner, the positive electrode member 22 is generally tubular. The positive electrode member 22 is located at the radially inner side of the evaporation source 21. The work W is located inside the evaporation source 21 in a state supported by the support 12. When an arc discharge is generated in the chamber 11, the arc discharge is generated between an inner circumferential surface 211 of the evaporation source 21 and the positive electrode member 22.

Further, the arc discharge generation device 20 includes a striker 24, an actuator 25, and a controller 40. The striker 24 is configured to be movable in the chamber 11. The actuator 25 drives and moves the striker 24. The controller 40 controls and drives the actuator 25. The striker 24 includes a striker tip 241 and a striker body 242 that supports the striker tip 241. The striker body 242 is rotationally supported by a support shaft 26 that is connected to ground. The striker tip 241 is located at a distal end of the striker body 242.

The striker 24 is driven by the actuator 25 and pivotal between a retraction position, which is shown by the solid line in FIG. 1, and a contact position, which is shown by the broken line in FIG. 1. When the striker 24 is located at the retraction position, the striker tip 241 does not contact the evaporation source 21. When the striker 24 is located at the contact position, the striker tip 241 contacts the evaporation source 21. In this regard, the striker tip 241 functions as a contact portion of the striker 24 that contacts the evaporation source 21.

The striker tip 241 is formed from graphite, which is an example of a material that is conductive and sublimable. The sublimation point of graphite (3550° C.) is higher than the boiling point of the material (titanium in the present embodiment) that forms the evaporation source 21 (3280° C.). The striker body 242 is formed from, for example, a stainless steel.

Further, the arc discharge generation device 20 includes a power supply device 30 that energizes the evaporation source 21. The power supply device 30 includes a negative power supply 31, a switching element 32, and a choke coil 33. The negative power supply 31 applies a negative DC voltage to the evaporation source 21. The controller 40 controls activation and deactivation of the switching element 32. The choke coil 33 is located between the switching element 32 and the evaporation source 21. A first gas arrester 34 is connected to the end of the choke coil 33 that is closer to the negative power supply 31. A second gas arrester 35 is connected to the end of the choke coil 33 that is closer to the evaporation source 21. When the controller 40 activates the switching element 32, a negative DC voltage is applied from the negative power supply 31 to the evaporation source 21. As a result, the potential at the evaporation source 21 becomes lower than the potential at the positive electrode member 22, which is connected to ground. Thus, the evaporation source 21 functions as a negative electrode, and the positive electrode member 22 functions as a positive electrode.

In the film formation method of the film formation device 10, when forming a titanium film on the work W in the chamber 11, a negative bias voltage is applied to the work W, which is supported by the support 12. Further, when the switching element 32 of the power supply device 30 is activated, a negative DC voltage is applied to the evaporation source 21. In this manner, under a situation in which the positive electrode member 22 functions as a positive electrode and the evaporation source 21 functions as a negative electrode, the striker 24 moves from the retraction position to the contact position and comes into contact with the evaporation source 21. Subsequently, when the striker 24 starts to move from the contact position toward the retraction position, the striker tip 241 is separated from the evaporation source 21. This generates electric sparks. As a result, an arc discharge is generated between the evaporation source 21 and the positive electrode member 22. Further, the arc discharge emits titanium ions from the evaporation source 21. The titanium ions are deposited on the work W to form a titanium film on the work W. When the film is being formed on the work W, the striker 24 waits at the retraction position.

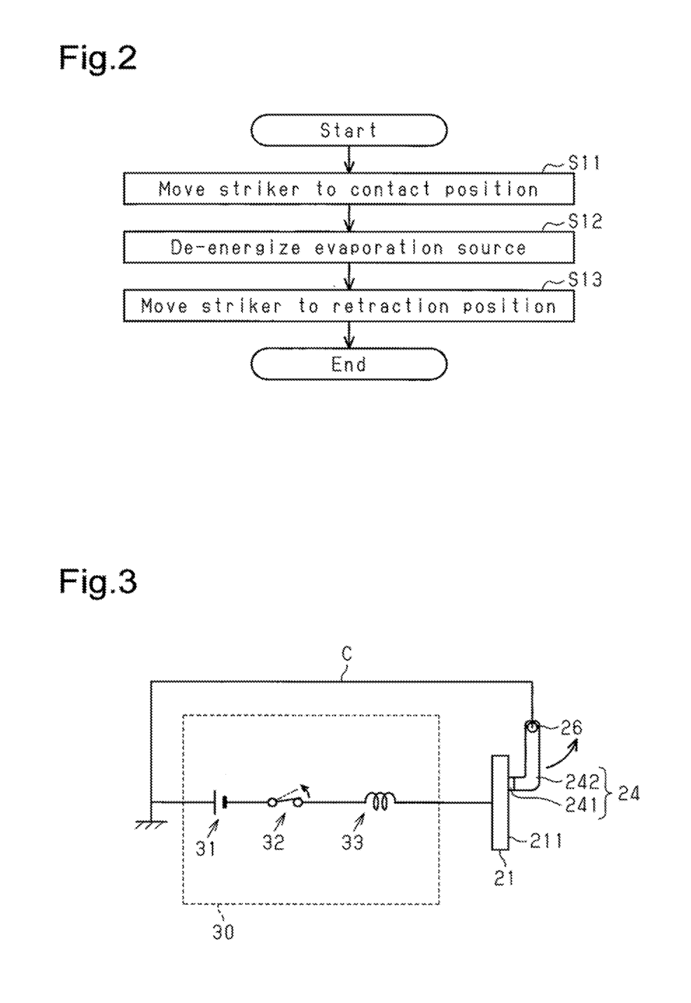

When film formation on the work W is completed, the power supply device 30 de-energizes the evaporation source 21 to extinguish the arc discharge generated in the chamber 11. Next, a processing routine executed by the controller 40 when extinguishing an arc discharge will be described with reference to the flowchart shown in FIG. 2.

Referring to FIG. 2, the controller 40 moves the striker 24 from the retraction position to the contact position by controlling and driving the actuator 25 (step S11). Next, the controller 40 deactivates the switching element 32 and de-energizes the evaporation source 21 (step S12). Then, the controller 40 moves the striker 24 from the contact position to the retraction position by controlling and driving the actuator 25 (step S13). Then, the controller 40 ends the processing routine.

The operation and advantage of the film formation method of the present invention, that is, extinguishment of an arc discharge generated in the chamber 11, will now be described with reference to FIG. 3. In FIG. 3, the configuration of the power supply device 30 is simplified.

The solid line in FIG. 3 indicates a situation in which the switching element 32 of the power supply device 30 is activated, that is, a situation in which the power supply device 30 is energizing the evaporation source 21. In this situation, when the striker 24 moves from the retraction position to the contact position, the striker tip 241 comes into contact with the evaporation source 21. This electrically connects the striker 24 to ground and forms an electric circuit C including the evaporation source 21. That is, the evaporation source 21 is electrically connected to ground via the striker 24.

When the switching element 32 is deactivated in this state as shown by the broken line in FIG. 3, the power supply device 30 de-energizes the evaporation source 21. This generates a high voltage at the choke coil 33 of the power supply device 30, and the high voltage is applied to the evaporation source 21. In this case, current flows through the electric circuit C and reduces electric charges that are accumulated in the evaporation source 21. As a result, the potential difference between the evaporation source 21 and a wall surface of the chamber 11 does not become large. This limits the generation of an arc discharge between a portion of the wall surface of the chamber 11 and the evaporation source 21. That is, when an arc discharge generated in the chamber 11 is extinguished, the generation of an arc discharge between a portion of the wall surface of the chamber 11 and the evaporation source 21 is limited.

When an arc discharge occurs between the evaporation source 21 and the positive electrode member 22, the temperature of the inner circumferential surface 211 of the evaporation source 21 is extremely high. Thus, when an arc discharge is extinguished, a molten pool may be formed at a portion of the evaporation source 21 that is in contact with the striker tip 241. In this case, the temperature of the molten pool of the evaporation source 21 may be higher than the melting point of the material that forms the evaporation source 21.

In general, a tip formed from molybdenum is used as a striker tip. The melting point of molybdenum is 2623° C. When a striker tip formed from molybdenum contacts the evaporation source 21 to extinguish an arc discharge, increases in temperature may cause a portion of the striker tip to undergo phase transition from a solid to a liquid. When a portion of the striker tip undergoes phase transition to a liquid, the striker tip will be welded to the evaporation source 21 and an arc discharge cannot be generated when forming a film on the next work W.

In this regard, in the present embodiment, the striker tip 241 is formed from graphite, which is a sublimable material. Thus, when the striker tip 241 contacts the evaporation source 21 that has a high temperature, the temperature of the striker tip 241 will rise but the striker tip 241 will seldom undergo a phase transition from a solid to a liquid. This limits welding of the striker tip 241 to the evaporation source 21.

The sublimation point of the material that forms the striker tip 241 (i.e., graphite) is higher than the boiling point of the material that forms the evaporation source 21 (i.e., titanium). Thus, when the striker tip 241 contacts the evaporation source 21, the temperature of the striker tip 241 will rise but the material of the striker tip 241 will seldom sublime.

It should be apparent to those skilled in the art that the present invention may be embodied in many other specific forms without departing from the spirit or scope of the invention. Particularly, it should be understood that the present invention may be embodied in the following forms.

When the striker tip 241 formed from a material having a melting point that is higher than the boiling point of the material of the evaporation source 21, the striker tip 241 will seldom undergo a phase transition from a solid to a liquid by contact with the evaporation source 21 that has a high temperature. This limits welding of the striker tip 241 to the evaporation source 21. That is, the material of the striker tip 241 does not have to be sublimable. The melting point of the material of the striker tip 241 does not have to be higher than the boiling point of the material forming the evaporation source 21 to limit welding. The generation of welding is limited as the melting point of the material of the striker tip 241 increases. For example, conductive ceramics such as tungsten carbide and titanium nitride are examples of a conductive material having a melting point that is higher than the melting point of molybdenum, which is generally used as the material of a striker tip.

When the striker tip 241 contacts the evaporation source 21 to extinguish an arc discharge, the chamber 11 may be supplied with inert gas such as argon to reduce the degree of vacuum in the chamber 11. In such a manner, when the degree of vacuum in the chamber 11 is decreased from that when forming a film, the effect of limiting the generation of an arc discharge when de-energizing the evaporation source 21 is further improved.

In addition, when supplying the chamber 11 with inert gas, the inert gas may be blown against a portion of the evaporation source 21 that contacts the striker tip 241. In this case, when inert gas is blown against the contact portion, the temperature of the contact portion decreases. This limits increases in the temperature of the striker tip 241 when the striker tip 241 contacts the evaporation source 21. Thus, when the striker tip 241 contacts the evaporation source 21, the striker tip 241 does not easily undergo phase transition from a solid to a liquid (or gas). This increases the materials that can be selected as the material of the striker tip 241.

The shape of the evaporation source 21 does not have to be tubular and may be flat.

As long as ions can be emitted by an arc discharge between the evaporation source 21 and the positive electrode member 22, the evaporation source 21 may be formed from a material other than titanium (for example, chromium nitride).

When generating an arc discharge in the chamber 11, a positive DC voltage may be applied to the positive electrode member 22.

In the above embodiment, a film is formed on the work W in the chamber 11 in which an arc discharge is generated. Instead, the film formation device may separately include a chamber in which an arc discharge is generated, that is, a first chamber including the evaporation source 21, and a second chamber including the work W so that the two chambers are in communication with each other through a communication passage. In this case, metal ions emitted from the evaporation source 21 by an arc discharge in the first chamber are guided into the second chamber through the communication passage, and a metal film is formed on the work W in the second chamber.

The present examples and embodiments are to be considered as illustrative and not restrictive, and the invention is not to be limited to the details given herein, but may be modified within the scope and equivalence of the appended claims.

1. An arc discharge generation device comprising:
an evaporation source located in a chamber;
a striker configured to be movable in the chamber;
an actuator that drives and moves the striker;
a power supply device that energizes the evaporation source; and
a controller that controls the actuator and the power supply device, wherein
the controller energizes the evaporation source with the power supply device so that the evaporation source functions as a negative electrode and controls the actuator to have the striker contact the evaporation source and then separate the striker from the evaporation source to generate an arc discharge in the chamber and emit ions from the evaporation source through the arc discharge, and
when extinguishing the arc discharge generated in the chamber, the controller controls the actuator to have the striker contact the evaporation source and de-energize the evaporation source with the power supply device in a situation in which the striker is in contact with the evaporation source.

2. The arc discharge generation device according to claim 1, wherein
the striker includes a contact portion that contacts the evaporation source, and
the contact portion is formed from a sublimable material.

3. The arc discharge generation device according to claim 2, wherein a sublimation point of a material that forms the contact portion of the striker is higher than a boiling point of a material that forms the evaporation source.

4. The arc discharge generation device according to claim 1, wherein
the striker includes a contact portion that contacts the evaporation source, and
a melting point of a material that forms the contact portion is higher than a boiling point of a material that forms the evaporation source.

5. A method for forming a film, the method comprising:
energizing an evaporation source arranged in a chamber with a power supply device so that the evaporation source functions as a negative electrode;
generating an arc discharge in the chamber by having a striker contact the evaporation source and then separating the striker from the evaporation source;
forming a film on a work with ions emitted from the evaporation source by the arc discharge; and
when extinguishing the arc discharge generated in the chamber, having the striker contact the evaporation source and de-energizing the evaporation source with the power supply device in a situation in which the striker is in contact with the evaporation source.
